(19) United States
(12) Patent Application Publication
(10) Pub. No.: US 2003/0141187 A1
(43) Pub. Date: Jul. 31, 2003

(54) Cesium vapor emitter and method of fabrication the same

(75) Inventors: Minho Sohn, Glen Rock, NJ (US); Seungdeok Kim, Moonachie, NJ (US); Steven Kim, Harrington Park, NJ (US)

Correspondence Address: MORGAN LEWIS & BOCKIUS LLP, 1111 PENNSYLVANIA AVENUE NW, WASHINGTON, DC, 20004, US

(73) Assignee: PLASMION CORPORATION

(21) Appl. No.: 10/058,340

(22) Filed: Jan. 30, 2002

(51) Int. Cl. C23C 14/34; E03B 11/00; C01D 1/32; B22F 1/02

(52) U.S. Cl. 204/298.07; 419/30; 419/40; 423/179; 423/184; 137/268

(57) ABSTRACT

The specification and drawings describe and show embodiments of the present invention in the cesium vapor emitter and the method of fabricating the same. More specifically, the cesium vapor emitter of the present invention includes a housing having at least one chamber therein and at least one channel, wherein the channel has a size wide enough to introduce a desired amount of cesium vapor, a cesium reservoir placed in the chamber, wherein the cesium reservoir is filled with a cesium pellet and a plug located between the cesium pellet and the channel, thereby emitting the cesium vapor from the cesium pellet through the channel, and a stopper securing the cesium reservoir in the chamber, so that the cesium vapor is emitted through the channel.

### BACKGROUND OF THE INVENTION

1. Field of the Invention

The present invention relates to an apparatus for producing negative ions in a thin film process, and more particularly, to a cesium vapor emitter and method of fabricating the same. Although the present invention is suitable for a wide scope of applications, it is particularly suitable for introducing a cesium dose in a precise and reliable way.

2. Discussion of the Related Art

It is well known that a coating of low electron affinity elements on any metal surface reduces the work function of the surface of the substrate, so that the population of electrons at the surface is enhanced by the presence of such an element. Among the low electron affinity elements, cesium (Cs) is the most efficient since it has the lowest electron affinity. Accordingly, cesium has been the most popular element in this regard.

Cesium sources have been developed for an ion beam deposition system, an electron tube for a display or camera tube, an electro-lithographic application, an electron microscopy, or any other photoelectron generator such as mass spectrometry and electron beam semiconductor lithography.

However, the use of cesium as a work function reducer often causes many problems. For example, cesium is very sensitive to oxidizing gases such as water vapor, oxygen, and carbon dioxide. In addition, cesium has a very high vapor pressure, so that it is difficult to control in the system. Furthermore, electron stimulated desorption (ESD) occurs since electrons emitted from the surface induce desorption of cesium, especially from slightly oxidized surfaces.

Accordingly, there is a demand to develop a precise and reliable cesium vapor emitter for the above-described industries.

### SUMMARY OF THE INVENTION

Accordingly, the present invention is directed to a cesium vapor emitter and a method of fabricating the same that substantially obviates one or more of problems due to limitations and disadvantages of the related art.

Another object of the present invention is to provide a cesium vapor emitter and a method of fabricating the same that provides a precise and reliable delivery of the cesium vapor in the various applications.

Additional features and advantages of the invention will be set forth in the description that follows and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a cesium vapor emitter includes a housing having at least one chamber therein and at least one channel, wherein the channel has a size wide enough to introduce a desired amount of cesium vapor, a cesium reservoir placed in the chamber, wherein the cesium reservoir is filled with a cesium pellet and a plug located between the cesium pellet and the channel, thereby emitting the cesium vapor from the cesium pellet through the channel, and a stopper securing the cesium reservoir in the chamber, so that the cesium vapor is emitted through the channel.

In another aspect of the present invention, a negative ion sputter source includes an electrode receiving an electrical potential, a sputter target electrically coupled to the electrode, having a negative electrical potential higher than the electrode, and providing a plurality of source ions, and a cesium vapor emitter located close enough to provide the cesium vapor onto a reacting surface of the sputter target, wherein the cesium vapor emitter includes a housing having at least one chamber therein and at least one channel, wherein the channel has a size wide enough to introduce a desired amount of the cesium vapor and is located in close proximity to the sputter target and a cesium reservoir placed in the chamber, wherein the cesium reservoir is filled with a cesium pellet and a plug located between the cesium pellet and the channel, and a stopper securing the cesium reservoir in the chamber, so that the cesium vapor is emitted through the channel.

In a further aspect of the present invention, a method of fabricating a cesium vapor emitter includes preparing a stabilized cesium pellet, introducing the cesium pellet into a cesium reservoir, and sealing the cesium reservoir with a cesium pellet by using vacuum pressing.

In a further aspect of the present invention, a method of fabricating a stabilized cesium pellet includes mixing sodium-mordenite and cesium-chloride, heating the mixed sodium-mordenite and cesium-chloride, filtering the heated mixture through a vacuum frit, drying a residual powder in a hot vacuum oven, heating the dried powder high enough to stabilize a cesium-modernite powder, mixing the cesium-modernite powder with liquid cesium under an anti-oxidant environment to form a mixture, and sintering the mixture of cesium-modernite powder and liquid cesium.

In a further aspect of the present invention, a cesium slurry includes a first amount of cesium-mordenite powder, and a second amount of liquid cesium, wherein the first amount and the second amount are equal by weight.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention.

In the drawings:

FIG. 1 is a cross-sectional view illustrating a negative ion sputter system using an annular ring type cesium vapor emitter according to a first embodiment of the present invention;

FIG. 2 is a cross-sectional view illustrating a negative ion sputter system using an annular ring type cesium vapor emitter according to a second embodiment of the present invention;

FIG. 3 is an expanded perspective view of the cesium vapor emitter with a sputter target of FIG. 1;

FIG. 4 is an expanded perspective view of the cesium vapor emitter with a sputter target of FIG. 2;

FIG. 5 is a cross-sectional view of the portion “A” of the cesium vapor emitter of FIG. 1;

FIG. 6 is a cross-sectional view of a cesium reservoir of the cesium vapor emitter of FIG. 1;

FIG. 7 is a cross-sectional view of the portion “A” of a cesium reservoir of the cesium vapor emitter of FIG. 4;

FIG. 8 is a cross-sectional view of a cesium reservoir of the cesium vapor emitter of FIG. 2;

FIG. 9 is a schematic view illustrating a negative ion sputter system using a dual strip type cesium vapor emitter according to a third embodiment of the present invention;

FIG. 10 is a schematic view illustrating a negative ion sputter system using a dual strip type cesium vapor emitter according to a fourth embodiment of the present invention;

FIG. 11 is a cross-sectional view of the negative ion sputter system of FIG. 9;

FIG. 12 is a cross-sectional view of the negative ion sputter system of FIG. 10;

FIG. 13 is an expanded perspective view of the dual strip type cesium vapor emitter of FIG. 9;

FIG. 14 is an expanded perspective view of the dual strip type cesium vapor emitter of FIG. 10;

FIG. 15 is a schematic cross-sectional view of a negative ion sputter system using a wall mounting type cesium vapor emitter according to a fifth embodiment of the present invention;

FIG. 16 is a schematic cross-sectional view of a negative ion sputter system using a wall mounting type cesium vapor emitter according to a sixth embodiment of the present invention;

FIGS. 17A to 17D are cross-sectional views of an exemplary cesium vapor emitter and a wall mounter, a perspective view of the cesium vapor emitter, and a cross-sectional view of the portion “B” according to a seventh embodiment of the present invention;

FIGS. 18A to 18D are cross-sectional views of another exemplary cesium vapor emitter and a wall mounter, a perspective view of the cesium vapor emitter, and a cross-sectional view of the portion “C” according to an eighth embodiment of the present invention;

FIGS. 19A and 19B are a perspective view of an exemplary wall mounting type cesium vapor emitter having an annular ring and a cross-sectional view of the portion “D” according to a ninth embodiment of the present invention;

FIGS. 20A and 20B are a perspective view of another exemplary wall mounting type cesium vapor emitter having an annular ring and a cross-sectional view of the portion “E” according to a tenth embodiment of the present invention;

FIGS. 21A and 21B are a perspective view of another exemplary wall mounting type cesium vapor emitter having an annular ring and a cross-sectional view of the portion “F” according to an eleventh embodiment of the present invention;

FIGS. 22A and 22B are a perspective view of another exemplary wall mounting type cesium vapor emitter having an annular ring and a cross-sectional view of the portion “G” according to a twelfth embodiment of the present invention;

FIG. 23 is an experimental result showing that a cesium vapor emission from the cesium vapor emitter of the present invention is stable and consistent for a long period of time; and

FIG. 24 is an experimental result showing that a cesium vapor emission of the present invention is controllable by a temperature of the cesium vapor emitter.

### DETAILED DESCRIPTION OF THE ILLUSTRATED EMBODIMENTS

Reference will now be made in detail to the illustrated embodiments of the present invention, examples of which are illustrated in the accompanying drawings. Wherever possible, the same reference numbers will be used throughout the drawings to refer to the same or like parts.

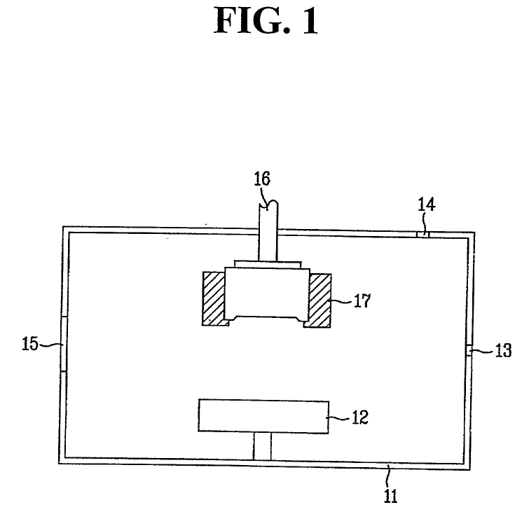

FIG. 1 schematically illustrates a negative ion sputter system having a cesium vapor emitter according to a first embodiment of the present invention. The negative ion sputter system is enclosed by a vacuum chamber 11. A pumping port 13 and a gas outlet port 14 are to maintain the sputter system under a desired vacuum condition. A substrate 12 to be treated is located in the sputter system and loaded through a loading port 15.

A sputter target 16 is placed in the system to face into the substrate 12. The substrate 12 and the sputter target 16 are spaced apart from each other by a desirable distance. A cesium vapor emitter 17 surrounds the sputter target 16 to provide cesium vapor in close proximity to the reacting surface of the sputter target 16. As previously mentioned, the presence of cesium on the target surface enhances the population of electrons at the surface since cesium reduces the work function of the surface. As a result, negatively charged ions are produced from the sputter target 16 in a sputtering process.

In FIG. 1, the cesium vapor emitter has an annular ring shape to match the shape of the sputter target 16 and the substrate 12. However, any kinds of different shapes may be implemented depending upon the shapes of the sputter target and the substrate. For example, a rectangular shape and a dual strip shape may also be used for the purpose of facilitating a contact between the emitted cesium vapor and the sputter target. More detailed descriptions will be made with reference to other embodiments of the present invention.

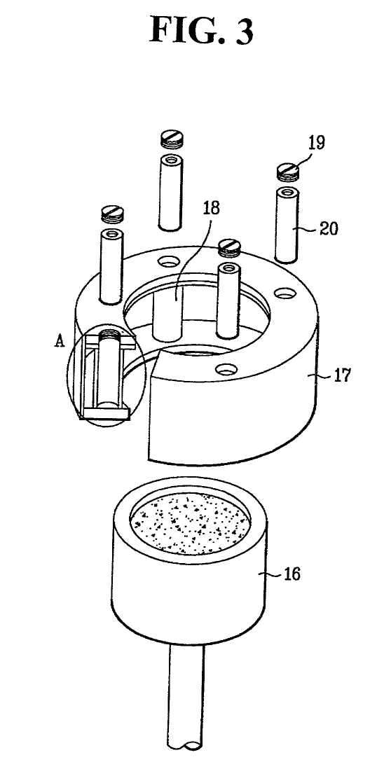

For a better understanding of the first embodiment of the present invention, the cesium vapor emitter having an annular ring shape is illustrated as an expanded perspective view in FIG. 3.

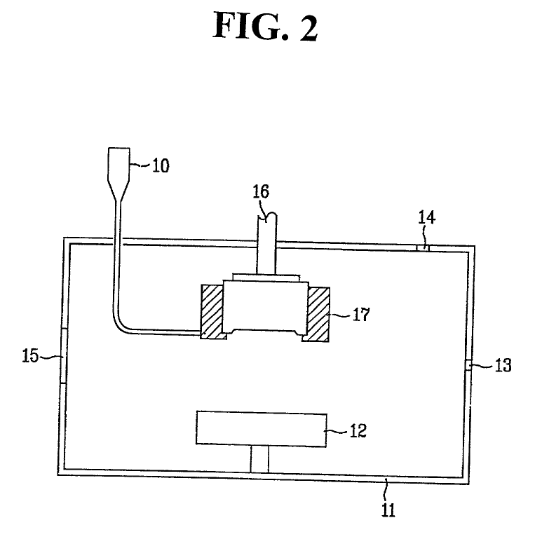

FIG. 2 schematically illustrates a negative ion sputter system having a cesium vapor emitter according to a second embodiment of the present invention. The negative ion sputter system is enclosed by a vacuum chamber 11. A pumping port 13 and a gas outlet port 14 are to maintain the sputter system under a desired vacuum condition. A substrate 12 to be treated is located in the sputter system and loaded through a loading port 15.

A sputter target 16 is placed in the system to face into the substrate 12. The substrate 12 and the sputter target 16 are spaced apart from each other by a desirable distance. A cesium vapor emitter 17 surrounds the sputter target 16 to provide cesium vapor in close proximity to the reacting surface of the sputter target 16. An inert gas supplier 10 is provided in close proximity to the cesium vapor emitter 17 for supplying an inert gas such as argon, for example, thereby creating a laminar flow through the cesium vapor emitter 17 and across the sputter target 16. Accordingly, the inert gas supplier 10 prevents oxygen and other gases from entering the cesium vapor emitter 17. As previously mentioned, the presence of cesium on the target surface enhances the population of electrons at the surface since cesium reduces the work function of the surface. As a result, negatively charged ions are produced from the sputter target 16 in a sputtering process.

In FIG. 2, the cesium vapor emitter has an annular ring shape to match the shape of the sputter target 16 and the substrate 12. However, any kinds of different shapes may be implemented depending upon the shapes of the sputter target and the substrate. For example, a rectangular shape and a dual strip shape may also be used for the purpose of facilitating a contact between the emitted cesium vapor and the sputter target. More detailed descriptions will be made with reference to other embodiments of the present invention.

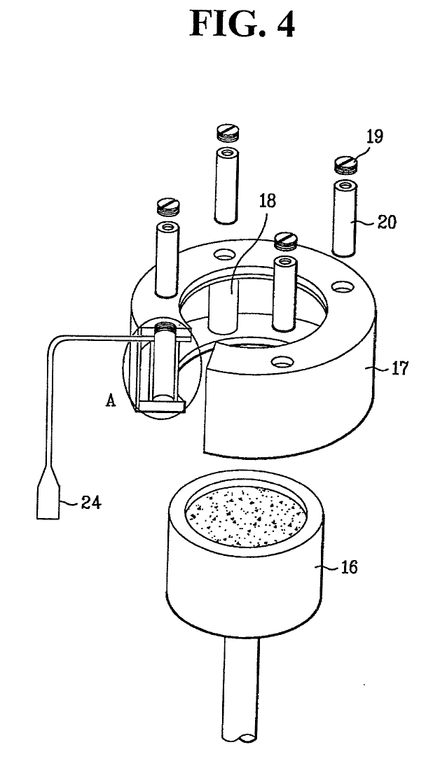

For a better understanding of the second embodiment of the present invention, the cesium vapor emitter having an annular ring shape is illustrated as an expanded perspective view in FIG. 4.

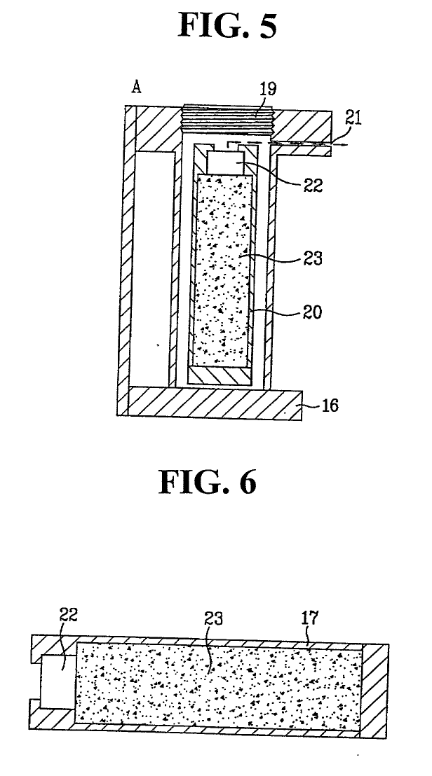

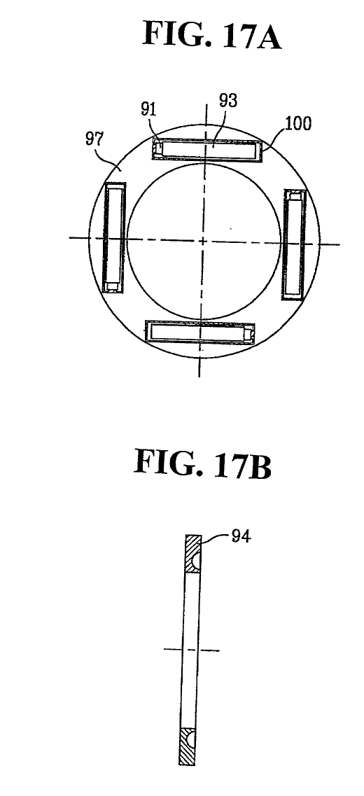

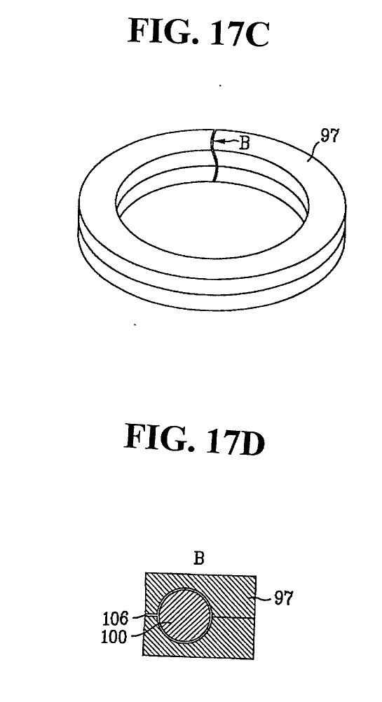

FIG. 3 is an expanded perspective view of the cesium vapor emitter with a sputter target of FIG. 1. In FIG. 3, the cesium vapor emitter includes a housing 17 having one or more chambers 18 and one or more cesium reservoirs 20 placed into each chamber. Further, the housing 17 has one or more channels 21 (shown in FIG. 5) or a slit 106 (in FIG. 17D) at the side close to the reacting surface of the sputter target 16. A stopper 19 is secured at each chamber after the cesium reservoirs 20 are placed into the chamber 18. Thereafter, the housing 17 and the sputter target are put into each other.

Cesium vapor is introduced onto the reacting surface of the sputter target through the channels or slit (not shown). There are no critical limitations in size and the number of channels or slits. As long as it provides a desired amount of cesium vapor to the sputter target 16, any dimensions are acceptable in the present invention.

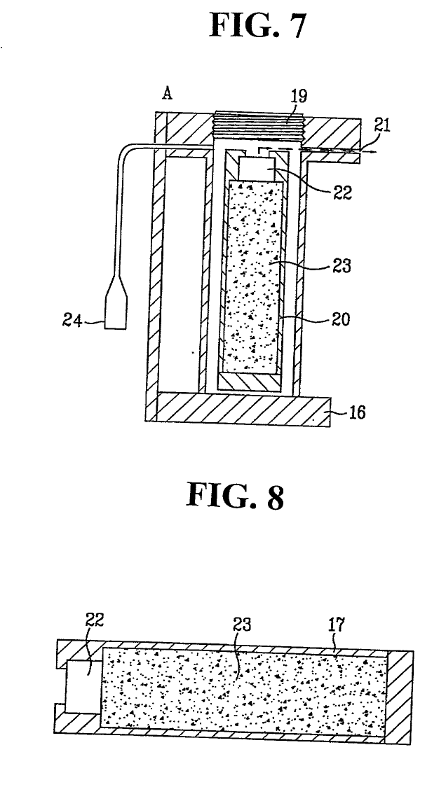

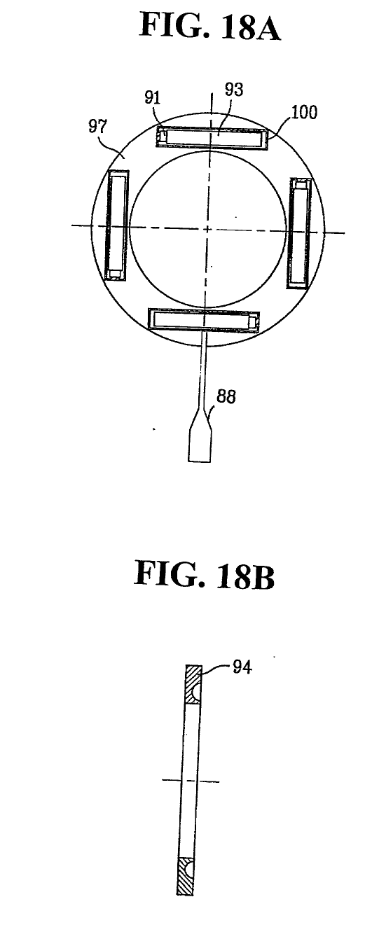

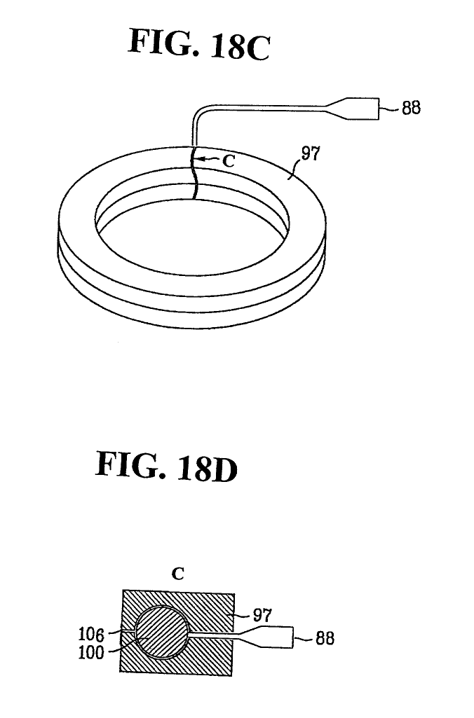

FIG. 4 is an expanded perspective view of the cesium vapor emitter with a sputter target of FIG. 2. In FIG. 4, the cesium vapor emitter includes a housing 17 having one or more chambers 18, and one or more cesium reservoirs 20 placed into each chamber, wherein each chamber 18 has an inert gas supplier 24 in close proximity to a corresponding one of the cesium reservoirs 20. Further, the housing 17 has one or more channels 21 (shown in FIG. 7) or a slit 106 (in FIG. 18D) at the side close to the reacting surface of the sputter target 16. A stopper 19 is secured at each chamber after the cesium reservoirs 20 are placed into the chamber 18. Thereafter, the housing 17 and the sputter target are put into each other.

Cesium vapor is introduced onto the reacting surface of the sputter target through the channels or slit (not shown). There are no critical limitations in size and the number of channels or slits. As long as it provides a desired amount of cesium vapor to the sputter target 16, any dimensions are acceptable in the present invention.

The cesium reservoir 20 is more fully discussed with reference to FIGS. 5 to 8. FIG. 5 is a cross-sectional view illustrating the portion “A” of FIG. 3 of the cesium vapor emitter of the present invention. FIG. 6 is a cross-sectional view of the cesium reservoir 20 of the present invention. FIG. 7 is a cross-sectional view illustrating the portion “A” of FIG. 4 of the cesium vapor emitter of the present invention. FIG. 8 is a cross-sectional view of the cesium reservoir 20 of the present invention.

As shown in FIGS. 5 and 7, the cesium reservoir 20 is filled with a cesium slurry 23, and the top portion of the cesium reservoir 20 is sealed with a plug 22. A shown in FIG. 7, an inert gas supplier 24 is in close proximity to the cesium reservoir 20. The cesium slurry 23 is a mixture of cesium-mordenite powder about 50% and pure liquid cesium about 50% by weight. The cesium-mordenite powder has a composition of Cs₂O.Al₂O₃.10SiO₂. The cesium slurry 23 stabilizes liquid state cesium in a form of slurry by mixing the liquid cesium with cesium-mordenite, which is stable cesium oxide. The cesium slurry 23 does not rapidly oxidize like liquid cesium even under the atmospheric pressure. The stabilized cesium slurry 23 is easy to control and convenient to use as a cesium vapor source. A cesium pellet may be used for the plug 22. The cesium pellet that may be fabricated from the cesium-mordenite powder by sintering. The cesium pellet prevents an excessive cesium vapor emission from the cesium slurry 23, so that only a desired amount of the cesium vapor is emitted from the channel 21 through the pellet. This is because the pellet has a porous structure. Alternatively, the plug 22 may be formed of a ceramic material such as Zeolite™, for example. Fabricating methods for the cesium slurry 23, the cesium-mordenite powder, and the cesium pellet will be more fully described later.

After the cesium reservoir 20 is placed into the chamber 18 (shown in FIGS. 3 and 4), a stopper 19 tightly seals the cesium reservoir 20, so that the cesium vapor is emitted from the channel 21 or slit only. The stopper 19 may be formed of the same material as the housing 17. For example, a chemically inert material such as stainless steel may be appropriate for the purpose of the present invention. Due to this structure, the cesium reservoir 20 is readily replaceable with a newly refilled reservoir if necessary.

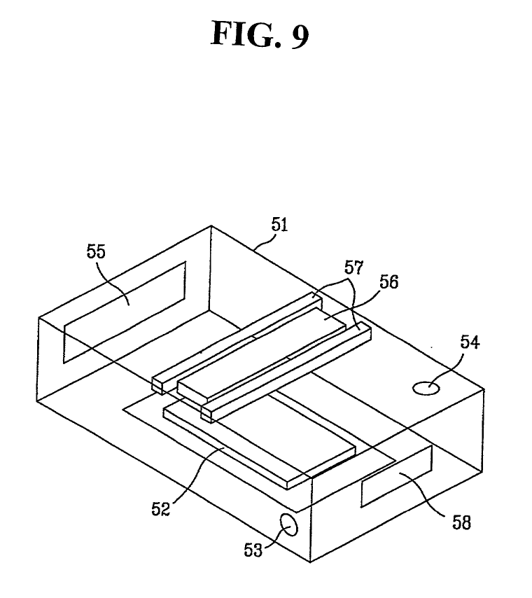

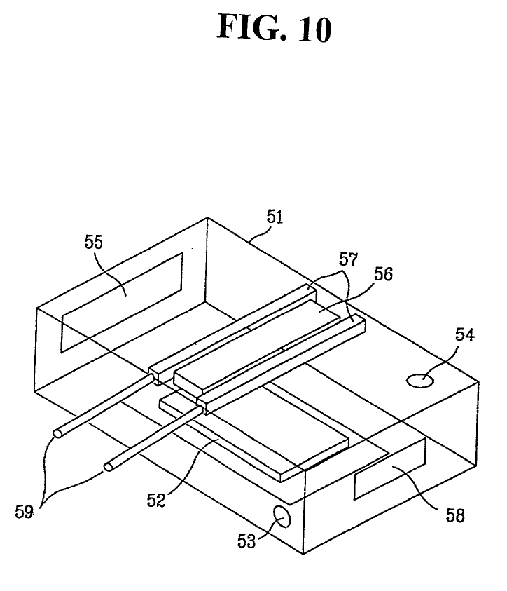

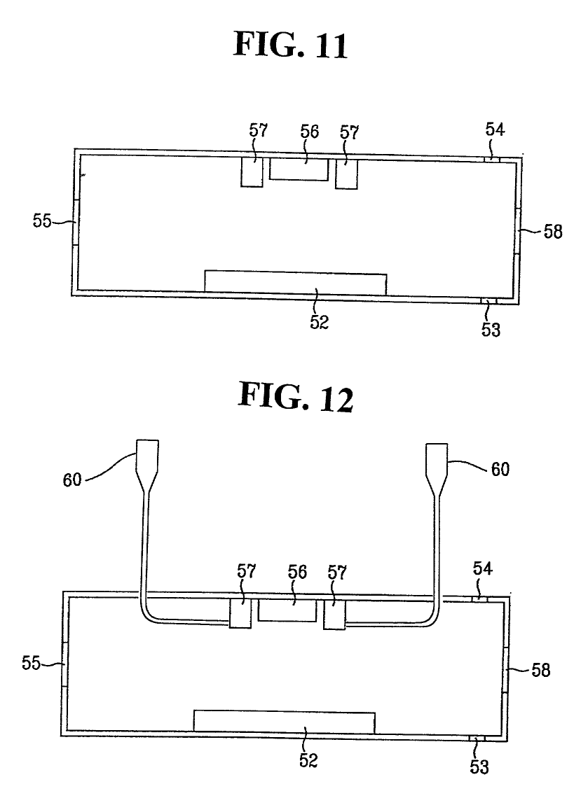

FIGS. 9 and 11 are a schematic view and a cross-sectional view respectively illustrating a negative ion sputter system using a dual strip type cesium vapor emitter according to a third embodiment of the present invention.

The third embodiment of the present invention may be applicable to treat a large sized rectangular substrate, such as a glass substrate for a liquid crystal display panel or a plasma display panel.

As shown in FIG. 9, a rectangular shaped substrate 52 is placed in the negative ion sputter system. For a better efficiency in sputtering, a sputter target 56 may have to match the shape of the substrate 52. Also, a dual strip type cesium vapor emitter 57 may provide a better efficiency in introducing cesium vapor onto the reacting surface of the sputter target 56 by matching the shape of the sputter target 56. Other elements are similar to those of the first embodiment except for the shapes of the sputter target 56 and the cesium emitter 57. Accordingly, detailed descriptions for the other elements will be omitted for simplicity.

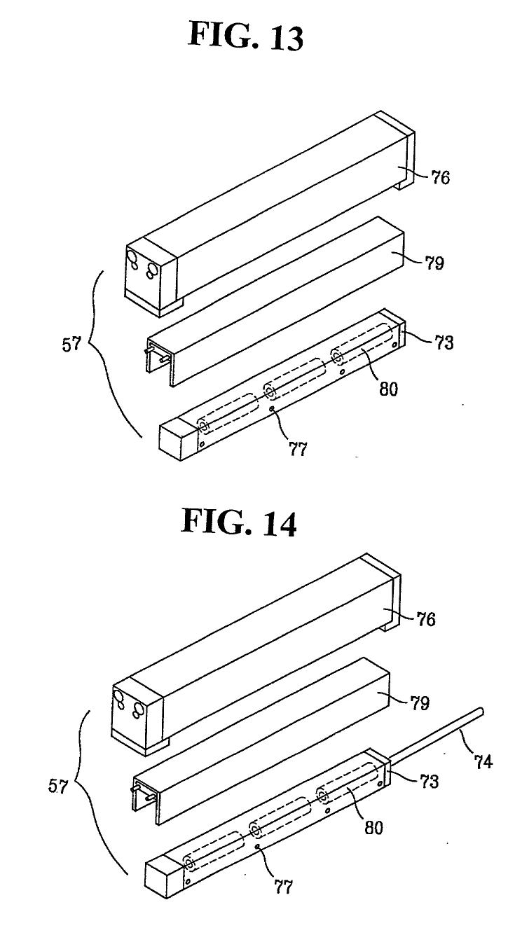

FIG. 13 is an expanded perspective view of the dual strip type cesium vapor emitter 56 of FIGS. 9 and 11. As shown in FIG. 13, one of the dual strip type cesium vapor emitter 56 includes first, second, and third parts 73, 76, and 79. Similar to the first embodiment, one or more cesium reservoirs 80 are located in the first part 73. Cesium vapor is introduced onto the reacting surface of the rectangular sputter target 56 (shown in FIGS. 9 and 11). Accordingly, by the use of cesium vapor on the sputter target, a high yield of negatively charged ions is produced from the sputter target.

FIGS. 10 and 12 are a schematic view and a cross-sectional view respectively illustrating a negative ion sputter system using a dual strip type cesium vapor emitter according to a fourth embodiment of the present invention.

The fourth embodiment of the present invention may be applicable to treat a large sized rectangular substrate, such as a glass substrate for a liquid crystal display panel or a plasma display panel.

As shown in FIG. 10, a rectangular shaped substrate 52 is placed in the negative ion sputter system. For a better efficiency in sputtering, a sputter target 56 may have to match the shape of the substrate 52. Also, a dual strip type cesium vapor emitter 57 may provide a better efficiency in introducing cesium vapor onto the reacting surface of the sputter target 56 by matching the shape of the sputter target 56. The dual strip type cesium vapor emitter 57 includes an inert gas supplier 59. Other elements are similar to those of the first embodiment except for the shapes of the sputter target 56 and the cesium emitter 57. Accordingly, detailed descriptions for the other elements will be omitted for simplicity.

FIG. 13 is an expanded perspective view of the dual strip type cesium vapor emitter 57 of FIGS. 9 and 11. As shown in FIG. 13, one of the dual strip type cesium vapor emitter 57 includes first, second, and third parts 73, 76, and 79. Similar to the first embodiment, one or more cesium reservoirs 80 are located in the first part 73. Cesium vapor is introduced onto the reacting surface of the rectangular sputter target 56 (shown in FIGS. 9 and 11). Accordingly, by the use of cesium vapor on the sputter target, a high yield of negatively charged ions is produced from the sputter target.

FIG. 14 is an expanded perspective view of the dual strip type cesium vapor emitter 57 of FIGS. 10 and 12. As shown in FIG. 14, one of the dual strip type cesium vapor emitter 57 includes first, second, and third parts 73, 76, and 79. Similar to the second embodiment, one or more cesium reservoirs 80 are located in the first part 73. Additionally, an insert gas supplier 74 is in close proximity to the cesium reservoirs 80. Cesium vapor is introduced onto the reacting surface of the rectangular sputter target 56 (shown in FIGS. 10 and 12). Accordingly, by the use of cesium vapor on the sputter target, a high yield of negatively charged ions is produced from the sputter target.

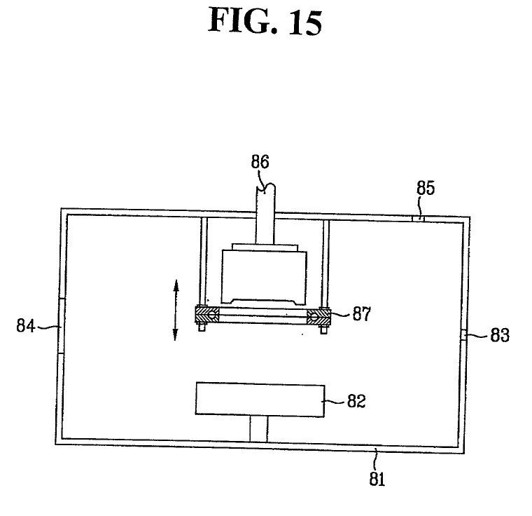

FIG. 15 is a schematic cross-sectional view of a negative ion sputter system using a wall mounting type cesium vapor emitter according to a fifth embodiment of the present invention.

The fifth embodiment is similar to the first and third embodiments except for the type of the cesium vapor emitter. Accordingly, detailed descriptions for the elements other than the cesium vapor emitter will be omitted.

As shown in FIG. 15, a wall mounting type cesium vapor emitter 87 is employed in the fifth embodiment. The wall mounting type cesium vapor emitter 87 is attached to a wall of a vacuum chamber 81 rather than a sputter target 86. The cesium vapor emitter 87 is attached by a wall mounter 94 (shown in FIG. 17B).

The sixth embodiment is similar to the second and fourth embodiments except for the type of the cesium vapor emitter. Accordingly, detailed descriptions for the elements other than the cesium vapor emitter will be omitted.

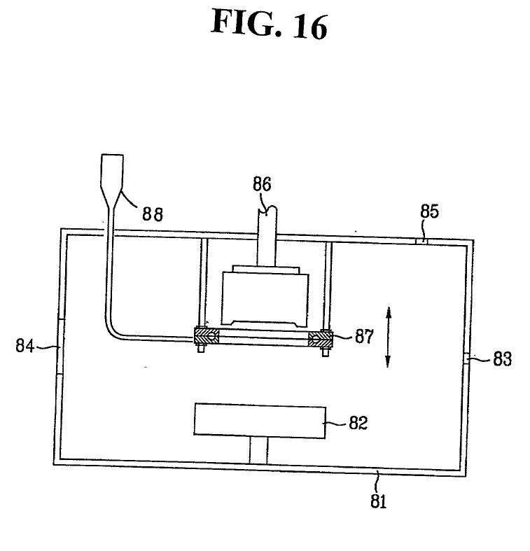

As shown in FIG. 16, a wall mounting type cesium vapor emitter 87 is employed in the sixth embodiment. The wall mounting type cesium vapor emitter 87 is attached to a wall of a vacuum chamber 81 rather than a sputter target 86. The cesium vapor emitter 87 is attached by a wall mounter 94 (shown in FIG. 18B). Additionally, an inert gas supplier is provided with the cesium vapor emitter 87.

Detailed exemplary features for the wall mount type cesium vapor emitter 87 of FIG. 15 will be described with reference to FIGS. 17A to 17D according to a seventh embodiment of the present invention.

A cross-sectional view of the cesium vapor emitter 87 of FIG. 15 is illustrated in FIG. 17A. A housing 97 has one or more cesium reservoirs 100 therein. Similar to the other embodiments, the cesium reservoir is filled with a cesium slurry 93 and sealed by a cesium pellet. The wall mounter 94 attaches the housing 97 to the wall of the vacuum chamber. Although the cesium vapor emitter in this embodiment is an annular ring shape, different shapes may be employed depending upon the shapes of the substrate to be treated and the sputter target.

FIGS. 17C and 17D illustrate a perspective view of the housing 97 of the cesium vapor emitter 87 and a cross-sectional view of the portion “B”. In the seventh embodiment, the cesium reservoir 100 may be placed in the housing 97 in parallel with the reacting surface of the sputter target. The wall mounting type cesium vapor emitter includes top and bottom parts, so that they are put together after placing the cesium reservoir 100 into the housing 97 by using vacuum pressing. Accordingly, the resulting housing 97 includes the slit 106 formed along an inner diameter of the housing 97.

Detailed exemplary features for the wall mount type cesium vapor emitter 87 of FIG. 16 will be described with reference to FIGS. 18A to 18D in accordance with an eighth embodiment of the present invention.

A cross-sectional view of the cesium vapor emitter 87 of FIG. 16 is illustrated in FIG. 18A. A housing 97 has one or more cesium reservoirs 100 therein. Similar to the other embodiments, the cesium reservoir is filled with a cesium slurry 93 and sealed by a cesium pellet. Additionally, an insert gas supplier 88 is provided with the housing 97. The wall mounter 94 attaches the housing 97 to the wall of the vacuum chamber. Although the cesium vapor emitter in this embodiment is an annular ring shape, different shapes may be employed depending upon the shapes of the substrate to be treated and the sputter target.

FIGS. 18C and 18D illustrate a perspective view of the housing 97 of the cesium vapor emitter 87 and a cross-sectional view of the portion “C”. In the eighth embodiment, the cesium reservoir 100 may be placed in the housing 97 in parallel with the reacting surface of the sputter target. The wall mounting type cesium vapor emitter includes top and bottom parts, so that they are put together after placing the cesium reservoir 100 into the housing 97 by using vacuum pressing. Accordingly, the resulting housing 97 includes the slit 106 formed along an inner diameter of the housing 97. In addition, the inert gas supplier is provided with the housing 87.

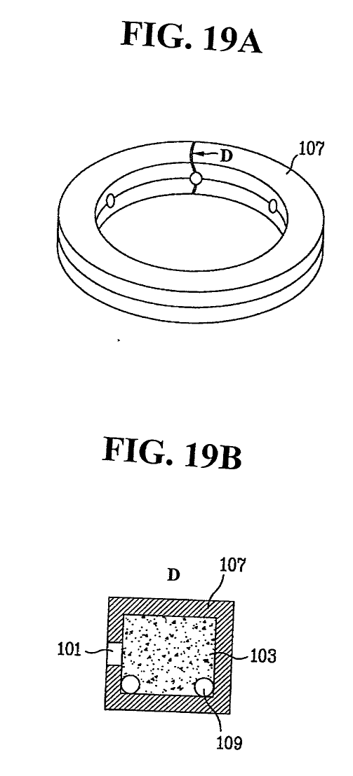

FIGS. 19A and 19B are a perspective view of an exemplary housing 107 of the wall mounting type cesium vapor emitter showing the cesium pellet 101 and a cross-sectional view of the portion “D” showing a heater 109 according to a ninth embodiment of the present invention.

As shown in FIGS. 19A and 19B, the cesium pellet 101 is filled in each channel of the housing 107. In order to adjust the temperature of the cesium slurry 103, one or more heaters 109 may be located in the cesium slurry 103. Thus, a desired amount of cesium vapor emission may be obtained by adjusting the cesium vapor emitter temperature. Although a heater is not described in the other embodiments, it may be applicable to all the other embodiments in the present invention.

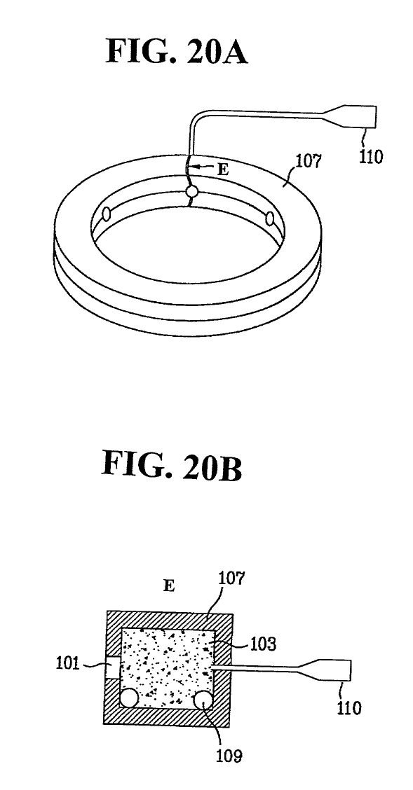

FIGS. 20A and 20B are a perspective view of another exemplary housing 107 of the wall mounting type cesium vapor emitter showing the cesium pellet 101 and a cross-sectional view of the portion “E” showing a heater 109 according to a tenth embodiment of the present invention.

As shown in FIGS. 20A and 20B, the cesium pellet 103 is filled in each channel of the housing 107. In order to adjust the temperature of the cesium pellet 103, one or more heaters 109 may be located in the cesium pellet 103. Thus, a desired amount of cesium vapor emission may be obtained by adjusting the cesium vapor emitter temperature. In addition, an inert gas supplier 110 is provided with the housing 107. Although a heater is not described in the other embodiments, it may be applicable to all the other embodiments in the present invention.

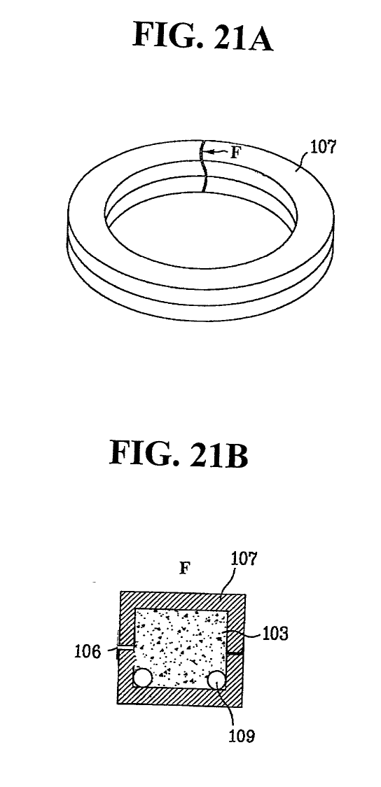

FIGS. 21A and 21B are a perspective view of another exemplary housing 107 of the wall mounting type cesium vapor emitter showing one of the plurality of cesium pellets 103 and a cross-sectional view of the portion “F” showing a heater 109 according to an eleventh embodiment of the present invention. In FIGS. 21A and 21B, the cesium pellet 103 may be placed in the housing 107 in parallel with the reacting surface of the sputter target. The wall mounting type cesium vapor emitter includes top and bottom parts, so that they are put together after placing the cesium pellets 103.

As shown in FIGS. 21A and 21B, the cesium pellet 103 is filled in each channel of the housing 107. In order to adjust the temperature of the cesium pellet 103, one or more heaters 109 may be located in the cesium pellet 103. Thus, a desired amount of cesium vapor emission may be obtained by adjusting the cesium vapor emitter temperature. Although a heater is not described in the other embodiments, it may be applicable to all the other embodiments in the present invention.

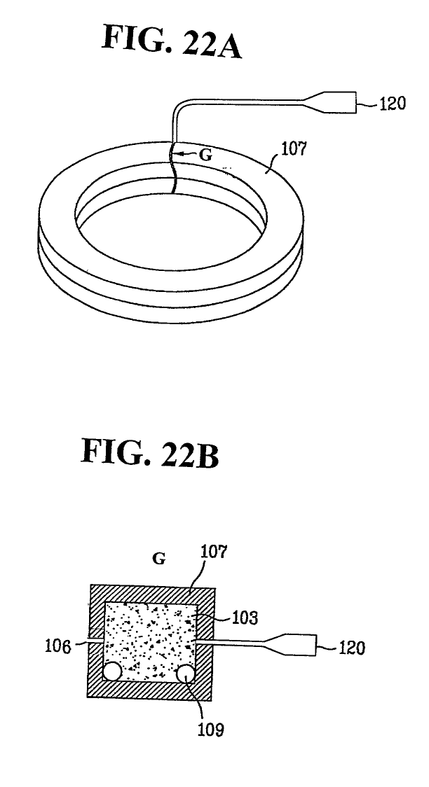

FIGS. 22A and 22B are a perspective view of another exemplary housing 107 of the wall mounting type cesium vapor emitter showing one of the plurality of cesium pellets 103 and a cross-sectional view of the portion “G” showing a heater 109 according to a twelfth embodiment of the present invention. In FIGS. 22A and 22B, the cesium pellet 103 may be placed in the housing 107 in parallel with the reacting surface of the sputter target. The wall mounting type cesium vapor emitter includes top and bottom parts, so that they are put together after placing the cesium pellets 103.

As shown in FIGS. 22A and 22B, the cesium pellet 103 is filled in each channel of the housing 107. In order to adjust the temperature of the cesium pellet 103, one or more heaters 109 may be located in the cesium pellet 103. Thus, a desired amount of cesium vapor emission may be obtained by adjusting the cesium vapor emitter temperature. In addition, an inert gas supplier 120 is provided with the housing 107. Although a heater is not described in the other embodiments, it may be applicable to all the other embodiments in the present invention.

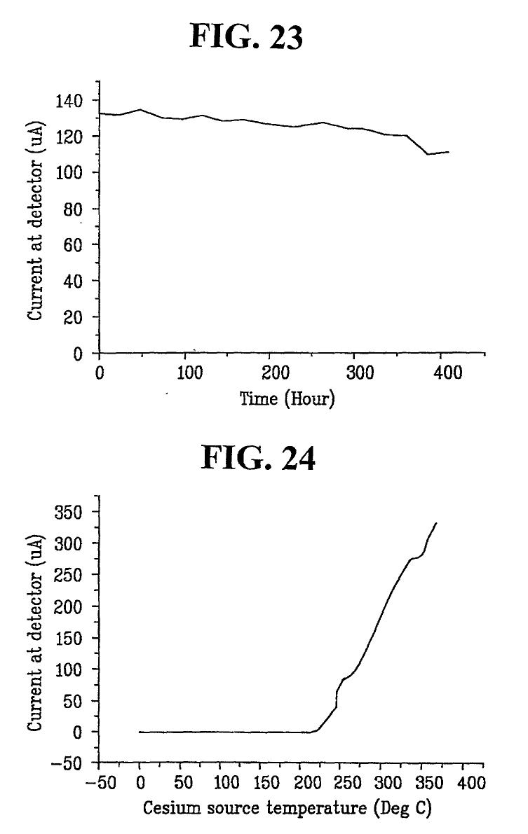

FIG. 23 is an experimental result showing detected ionized cesium vapor in close proximity to the cesium vapor emitter using a mass detector represented to ionize the cesium vapor and measure the ionized cesium current (IA) in the present invention. As shown in FIG. 23, a cesium emission from the cesium vapor emitter of the present invention is stable and consistent for a long period of time.

FIG. 24 is an experimental result showing detected ionized cesium vapor in close proximity to the cesium vapor emitter using a mass detector represented as ionized cesium current (IA) vs. a temperature at the cesium vapor emitter. Cesium vapor begins to emit from the cesium vapor emitter at the temperature of about 80° C. (i.e., emission temperature). However, an optimum emission temperature is in the range of about 150 to 250° C. as shown in FIG. 24. Also, the cesium vapor emission is linearly increased with a temperature higher than the emission temperature. Therefore, it is demonstrated in the present invention that a cesium emission is controllable by regulating the temperature of the cesium vapor emitter.

A method of fabricating a cesium vapor emitter in the present invention will be described as follows.

Preparing a stabilized cesium slurry is necessary in the present invention. The cesium slurry is prepared by mixing the same amount of cesium-mordenite powder and liquid cesium by weight under an anti-oxidant environment. A cesium slurry, known as Cemite™, may be appropriately mixed to have a homogeneous phase. Other cesium slurry mixtures will be known to those skilled in the art and are within the scope of the present invention.

Cesium-mordenite is a synthetic Zeolite™ having a composition of Cs₂O.Al₂O₃.10SiO₂. The cesium-mordenite powder is formed from sodium-mordenite power (Na₂O.Al₂O₃.10SiO₂) by ion exchange. The sodium cation is exchanged for cesium in a cesium-chloride (CsCl) solution. After the solution is heated at around 80° C. with magnetic stirring, it is filtered through a vacuum flit and dried in a hot vacuum oven. In order to stabilize the ion exchanged cesium-modernite, the dried powder is heated at least at around 1050° C. A detailed description for fabricating cesium-modernite was disclosed in “A New Solid-State Cesium Ion Source”, Journal of Applied Physics, Vol. 67, No. 6, pages 2704 to 2710 in 1990, which is hereby incorporated by reference.

As described above, a cesium pellet or Zeolite™ may be employed as a plug sealing the cesium slurry/pellet in the cesium reservoir. The plug prevents an excessive cesium vapor emission from the cesium reservoir. The cesium pellet may be fabricated from cesium-modernite powder by sintering.

More specifically, the cesium-modernite is crushed and sieved to have a desired particle size. The pre-sieved powder is mixed with deionized water and then ground using a high purity zirconia ball mill. After grinding, desired uniform sized particles are selected by a vacuum frit. Thereafter, the powder is press-formed by a cylindrical hardened steel plunger before sintering. The press-formed powder is sintered at around 1350° C. for about three hours. A detailed description for sintering cesium-mordenite was disclosed in “A New Solid-State Cesium Ion Source”, Journal of Applied Physics, Vol. 67, No. 6, pages 2704 to 2710 in 1990, which is hereby incorporated by reference.

Although a negative ion sputter system is exemplified in the present invention, the cesium vapor emitter of the present invention may be applicable to other applications such as an electron tube for a display or camera tube, an electro-lithographic application, an electron microscopy, or any other photoelectron generator such as mass spectrometry and electron beam semiconductor lithography.

It will be apparent to those skilled in the art that various modifications and variations can be made in the cesium vapor emitter and the method of fabricating the same of the present invention without departing from the spirit or scope of the inventions. Thus, it is intended that the present invention covers the modifications and variations of this invention provided they come within the scope of the appended claims and their equivalents.

What is claimed is:

1. A cesium vapor emitter, comprising:
a housing having at least one chamber therein and at least one channel, wherein the channel has a size wide enough to introduce a desired amount of cesium vapor;
a cesium reservoir placed in the chamber, wherein the cesium reservoir is filled with a cesium pellet and a plug located between the cesium pellet and the channel, thereby emitting the cesium vapor from the cesium pellet through the channel; and
a stopper securing the cesium reservoir in the chamber, so that the cesium vapor is emitted through the channel.

2. The cesium vapor emitter according to claim 1, wherein the cesium pellet includes cesium slurry.

3. The cesium vapor emitter according to claim 1, wherein the plug is formed of a cesium pellet.

4. The cesium vapor emitter according to claim 3, wherein the cesium pellet includes a sintered cesium-mordenite.

5. The cesium vapor emitter according to claim 4, wherein the sintered cesium-mordernite has a composition of Cs₂O.Al₂O₃.10SiO₂.

6. The cesium vapor emitter according to claim 1, wherein the cesium pellet is a mixture of cesium-mordenite powder 50%-liquid cesium 50% by weight.

7. The cesium vapor emitter according to claim 1, wherein the housing has a shape of one of annular ring, rectangular, and dual strip types.

8. The cesium vapor emitter according to claim 1, wherein the cesium reservoir is heated up to a range of about 150 to 200° C.

9. The cesium vapor emitter according to claim 1, further comprising an insert gas supplier in close proximity to the cesium reservoir for supplying an inert gas with the cesium vapor.

10. A negative ion sputter source, comprising:
an electrode receiving an electrical potential;
a sputter target electrically coupled to the electrode, having a negative electrical potential higher than the electrode, and providing a plurality of source ions; and
a cesium vapor emitter located close enough to provide a plurality of cesium vapor onto a reacting surface of the sputter target, wherein the cesium vapor emitter includes a housing having at least one chamber therein and at least one channel, wherein the channel has a size wide enough to introduce a desired amount of the cesium vapor and is located in close proximity to the sputter target and a cesium reservoir placed in the chamber, wherein the cesium reservoir is filled with a cesium pellet and a plug located between the cesium pellet and the channel, and a stopper securing the cesium reservoir in the chamber, so that the cesium vapor is emitted through the channel.

11. The cesium vapor emitter according to claim 10, wherein the plug is formed of a cesium pellet.

12. The cesium ion source according to claim 11, wherein the cesium pellet includes a cesium slurry.

13. The cesium vapor emitter according to claim 11, wherein the cesium pellet includes a sintered cesium-mordenite.

14. The cesium vapor emitter according to claim 13, wherein the sintered cesium-mordernite has a composition of Cs₂O.Al₂O₃.10SiO₂.

15. The cesium vapor emitter according to claim 10, wherein the cesium pellet is a mixture of cesium-mordenite powder 50%-liquid cesium 50% by weight.

16. The cesium vapor emitter according to claim 10, wherein the housing has a shape of one of annular ring, rectangular, and dual strip types.

17. The cesium vapor emitter according to claim 10, wherein the cesium reservoir is heated up to a range of about 150 to 250° C.

18. The cesium vapor emitter according to claim 10, further comprising an insert gas supplier in close proximity to the cesium reservoir for supplying an inert gas with the cesium vapor.

19. A method of fabricating a cesium vapor emitter, comprising:
preparing a stabilized cesium pellet;
introducing the cesium pellet into a cesium reservoir; and
sealing the cesium reservoir with a cesium pellet plug by using vacuum pressing.

20. The method according to claim 19, wherein the preparing a stabilized cesium pellet includes:
mixing sodium-mordenite and cesium-chloride;
heating the mixed sodium-mordenite and cesium-chloride;
filtering the heated mixture through a vacuum frit;
drying a residual powder in a hot vacuum oven;
heating the dried powder high enough to stabilize a cesium-modernite powder; and
mixing the cesium-modernite powder with liquid cesium under an anti-oxidant environment to obtain the cesium slurry.

21. The method according to claim 20, wherein the mixed sodium-mordenite and cesium-chloride are heated at about 80° C.

22. The method according to claim 20, wherein the dried powder is heated at least at about 1050° C.

23. The method according to claim 20, wherein the cesium-modernite power and the liquid cesium is mixed with the same amount by weight.

25. The method according to claim 19, wherein the cesium pellet plug includes a cesium pellet.

26. The method according to claim 25, wherein the cesium pellet includes a sintered cesium-mordenite.

27. The method according to claim 26, wherein the sintered cesium-mordernite has a composition of Cs₂O.Al₂O₃.10SiO₂.

28. A method of fabricating a stabilized cesium pellet, comprising:
mixing sodium-mordenite and cesium-chloride;
heating the mixed sodium-mordenite and cesium-chloride;
filtering the heated mixture through a vacuum frit;
drying a residual powder in a hot vacuum oven;
heating the dried powder high enough to stabilize a cesium-modernite powder;
mixing the cesium-modernite powder with liquid cesium under an anti-oxidant environment to form a mixture; and
sintering the mixture of cesium-modernite powder and liquid cesium.

29. The method according to claim 28, wherein the mixed sodium-mordenite and cesium-chloride are heated at about 80° C.

30. The method according to claim 28, wherein the dried powder is heated at least at about 1050° C.

31. The method according to claim 28, wherein the cesium-modernite power and the liquid cesium is mixed with the same amount by weight.

32. A cesium slurry, comprising:
a first amount of cesium-mordenite powder; and
a second amount of liquid cesium,
wherein the first amount and the second amount are equal by weight.

33. The cesium slurry according to claim 32, wherein the cesium-mordenite has a composition of Cs₂O.Al₂O₃.10SiO₂.

34. The cesium slurry according to claim 32, wherein the cesium-mordenite is sintered.
